(19) United States
(12) Patent Application Publication
(10) Pub. No.: US 2015/0043136 A1
(43) Pub. Date: Feb. 12, 2015

(54) DISPLAY APPARATUS

(71) Applicant: SAMSUNG ELECTRONICS CO., LTD., Suwon-si (KR)

(72) Inventors: Song Hyeon KIM, Incheon (KR); Jeong Roh LEE, Hwaseong-si (KR); Jin JUNG, Hwaseong-si (KR); Kwang Sung HWANG, Suwon-si (KR); Sung Soo JUNG, Suwon-si (KR)

(73) Assignee: SAMSUNG ELECTRONICS CO., LTD., Suwon-si (KR)

(21) Appl. No.: 14/337,780

(22) Filed: Jul. 22, 2014

(30) Foreign Application Priority Data
Aug. 8, 2013 (KR) 10-2013-0094158
Aug. 8, 2013 (KR) 10-2013-0094159
Dec. 3, 2013 (KR) 10-2013-0148962

(51) Int. Cl. H05K 5/00; H02P 31/00; H02K 7/116

(52) U.S. Cl. CPC H05K 5/0017; H02K 7/116; H02P 31/00; H05K 2201/05
USPC 361/679.01; 310/83; 318/16

(57) ABSTRACT

Disclosed herein is a display apparatus which may be selectively used in a flat state or a curved state. The display apparatus includes a display module that displays an image and is provided to be bent, and a bending device that is provided to enable the display module to be transformed into a flat state or a curved state. Here, the bending device includes a frame that is provided at a rear side of the display module and a hinge unit that connects between the frames and is provided to enable curvature of the frame to vary by torque.

### CROSS-REFERENCE TO RELATED APPLICATION

This application claims the benefit of Korean Patent Application Nos. 10-2013-0094158, 10-2013-0094159 and 10-2013-0148962, filed on Aug. 8, 2013, Aug. 8, 2013 and Dec. 3, 2013, respectively, in the Korean Intellectual Property Office, the disclosure of which is incorporated herein by reference.

### BACKGROUND

1. Field

Exemplary embodiments relate to a display apparatus.

2. Description of the Related Art

In general, display apparatuses are devices including a display module for displaying images, and include televisions and monitors. Among such display apparatuses, there are display apparatuses that use a display module including an organic light-emitting diode (OLED) panel.

Since the OLED panel is made of a material capable of being deformed within a predetermined range, display apparatuses whose display panel is fixed and installed in a curve surface state, whereby a user can partially experience a three-dimensional (3D) effect of a 3D image even through a two-dimensional image, have recently been proposed.

However, some users may prefer flat display modules to curved display modules.

In addition, the curved display module is required in order to improve a sense of immersion when viewed by a single user, but there is a problem that the curved display module may cause inconvenience due to a limitation of a viewing angle when viewed by multiple users.

However, the conventional flat display panel may transfer more accurate images than the curved display panel, and therefore there may be cases in which the conventional flat display panel is more advantageous than the curved display panel, according to content being displayed.

### SUMMARY

Therefore, it is an aspect of the exemplary embodiments to provide a display apparatus which may selectively maintain a flat state or a curved state.

In addition, it is another aspect of the exemplary embodiments to provide a display apparatus in which curvature can vary depending on consumer's preference, thereby freely implementing curvature deformation of a display module.

Additional aspects of the exemplary embodiments will be set forth in part in the description which follows and, in part, will be obvious from the description, or may be learned by practice of the exemplary embodiments.

In accordance with one exemplary embodiment, a display apparatus includes a display module configured to display an image and is capable of being deformed, and a deforming device configured to transform the display module to be transformed into a flat state or a curved state. Here, the deforming device includes a frame provided at a rear side of the display module and a hinge unit configured to connect the frames and enables the curvature of the frame to vary by a torque applied to the deforming device.

Also, the frame may include a plurality of plates configured to vertically support the display at the rear side of the display module, and a handle that is provided at a first end plate and a second end plate.

Also, the hinge unit may include a first bracket connected to one of the plurality of plates and having a hinge hole formed therein, a second bracket connected to an adjacent one of the plurality of plates, configured to be connected to the first bracket and having a sleeve formed therein to correspond to the hinge hole, and a hinge shaft configured to pass through the hinge hole and the sleeve to connect the one of the plurality of plates and the adjacent one of the plurality of plates.

Also, the sleeve may be formed in a horizontal direction to enable the first bracket to slide.

Also, the hinge shaft may further include a stopper, and a support portion corresponding to the stopper formed on the second bracket.

Also, the support position may include a first support position in which the hinge shaft is positioned so that the plurality of plates contact each other, and a second support portion in which the hinge shaft is positioned so that the plates are spaced apart from each other.

Also, the frame may be fixed to the display module by a fixing member.

Also, the deforming device may include a bracket provided at the rear side of the display module, a plurality of link members provided at a front side of the bracket configured to support a rear surface of the display module, and a hinge unit that is provided to connect the link members.

Also, the plurality of link members may include a main link configured to move the display module in a vertical direction, at least one first link moveably connected to a first side and a second side of the main link, and a plurality of second links rotatably connected to the at least one first link and configured to rotate in a forward and rearward direction.

Also, the plurality of link members may further include at least one connection link configured to connect the main link and the at least one first link.

Also, the plurality of second links may be spaced apart from each other in a direction from a center of the at least one first link toward an end of the first link opposite from the main link, and a length of the plurality of second links may be increased from the center of the at least one first link toward the end of the first link.

Also, the hinge unit may include a first hinge configured to connect the main link and the at least one first link, a second hinge configured to connect the at least one connection link and the at least one first link, and a third hinge configured to connect the at least one first link and each of the plurality of second links.

Also, the display apparatus may further include a handle configured to vertically move the main link.

Also, the bracket may further include a guide configured to guide a movement of the main link.

Also, the display apparatus may further include a driving unit configured to vertically move the main link.

Also, the driving unit may include a first gear provided on the main link, a second gear configured to be engaged with the first gear, and a motor configured to rotate the second gear.

Also, the driving unit may include a controller configured to operate the motor, and the controller is provided in the frame.

Also, the display apparatus may further include: a remote controller configured to connect to the controller.

According to another exemplary embodiment, there is provided a deformation device including a frame including a plurality of plates, at least one hinge unit connected to the plurality of plates, such that the at least one hinge unit connects the plurality of plate, and a display connected to the frame, where the display device can be deformed by rotating the at least one hinge unit.

The at least one hinge unit may include a first bracket and a second bracket, and the first bracket may be connected to one of the plurality of plates and the second bracket may be connected to an adjacent one of the plurality of plates.

The fixing portion may be configured to connect the first bracket to the second bracket.

According to another exemplary embodiment, there is provided a deforming device including a bracket, at least one link member connected to the bracket, and a display connected to the bracket, where a movement of the at least one link member deforms the display device.

The at least one link member may include a main link, at least one first link moveably connected to the main link, and at least one second link moveably connected to the at least one first link, where the at least one second link is connected to the display.

The display device may be deformed from an original position to a deformed position when the movement is in a vertically upward direction, and the display device may be deformed from the deformed position to the original position when the movement is in a vertically downward direction.

### BRIEF DESCRIPTION OF THE DRAWINGS

These and/or other aspects of the invention will become apparent and more readily appreciated from the following description of the exemplary embodiments, taken in conjunction with the accompanying drawings of which:

FIG. 1 is a schematic perspective view showing a display apparatus in accordance with one exemplary embodiment;

FIG. 2 is a schematic perspective view showing a state of a curved surface of a display module of a display apparatus in accordance with one exemplary embodiment;

FIG. 3 is an exploded perspective view showing a deforming device of a display apparatus in accordance with one exemplary embodiment;

FIG. 4 is a schematic perspective view showing a deforming device of a display module in accordance with one exemplary embodiment;

FIG. 5 is a schematic view showing a hinge unit of a deforming device in accordance with one exemplary embodiment;

FIG. 6 is a schematic view showing a state of a display module by a deforming device in accordance with one exemplary embodiment;

FIGS. 7 to 9 are schematic views showing an operating state of a hinge unit in accordance with one exemplary embodiment;

FIG. 10 is a schematic view showing a hinge unit of a deforming device in accordance with another exemplary embodiment;

FIG. 11 is a schematic perspective view showing a display apparatus in accordance with another exemplary embodiment;

FIG. 12 is a schematic perspective view showing a curved surface state of a display module of a display apparatus in accordance with another exemplary embodiment;

FIG. 13 is a schematic exploded perspective view showing a deforming device of a display apparatus in accordance with another exemplary embodiment;

FIG. 14 is a schematic exploded perspective view showing a deforming device in accordance with another exemplary embodiment;

FIGS. 15 and 16 are schematic views showing operations of a link member in accordance with another exemplary embodiment;

FIGS. 17 and 18 are schematic views showing an operating state of a display module by a deforming device in accordance with another exemplary embodiment; and

FIG. 19 is a schematic view showing a deforming device in accordance with another exemplary embodiment.

### DETAILED DESCRIPTION

Reference will now be made in detail to the exemplary embodiments, examples of which are illustrated in the accompanying drawings, wherein like reference numerals refer to like elements throughout.

In the following description, like drawing reference numerals are used for the like elements, even in different drawings. The matters defined in the description, such as detailed construction and elements, are provided to assist in a comprehensive understanding of exemplary embodiments. However, exemplary embodiments can be practiced without those specifically defined matters. Also, well-known functions or constructions are not described in detail since they would obscure the application with unnecessary detail.

Expressions such as “at least one of,” when preceding a list of elements, modify the entire list of elements and do not modify the individual elements of the list.

Hereinafter, the term “unit” refers to a software component, or a hardware component such as FPGA or ASIC, and performs a certain function. However, the “unit” is not limited to software or hardware. The “unit” may be configured in an addressable storage medium and may be configured to be executed by one or more processors. Hence, the “unit” includes elements such as software elements, object-oriented software elements, class elements, and task elements, and processes, functions, attributes, procedures, subroutines, segments of program codes, drivers, firmware, micro-codes, circuits, data, databases, data structures, tables, arrays, and variables. The functions provided in the elements and the units may be combined into a fewer number of elements and units or may be divided into a larger number of elements and units.

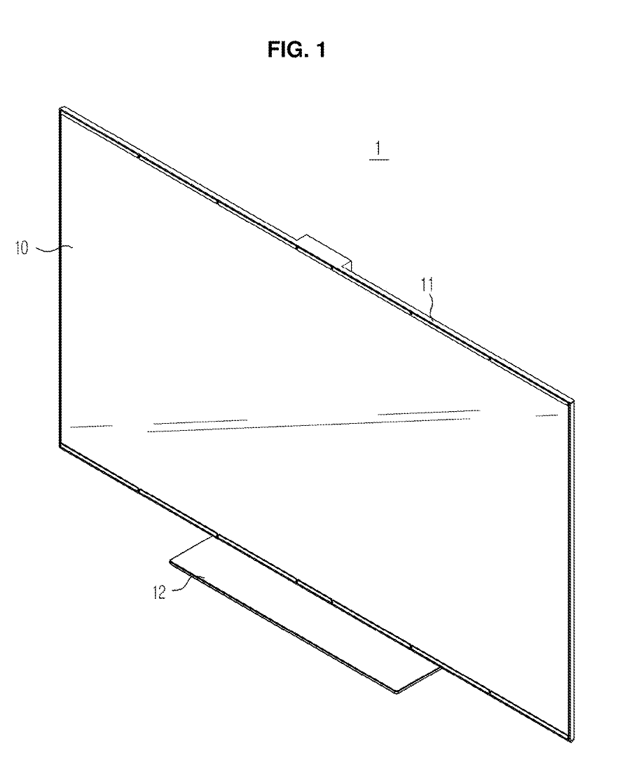

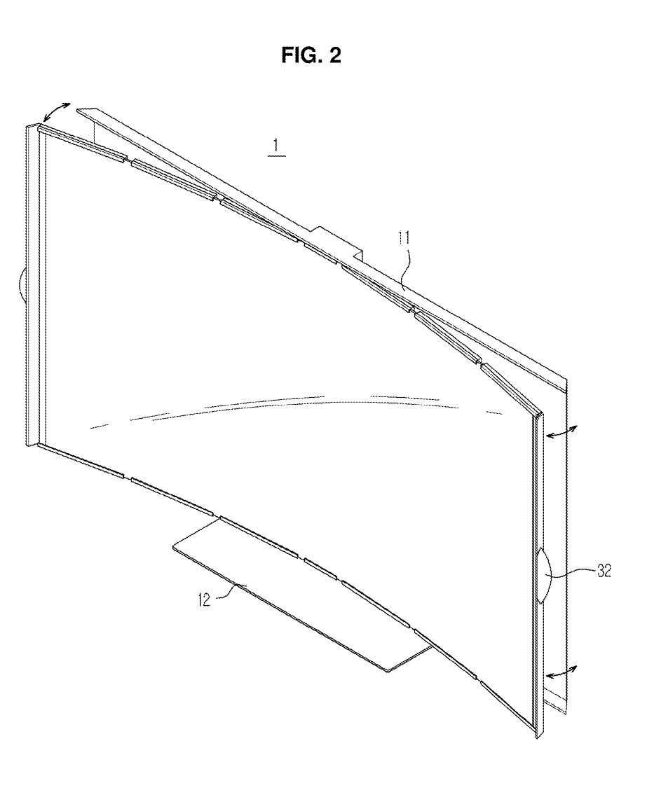

FIG. 1 is a schematic perspective view showing a display apparatus in accordance with one exemplary embodiment, and FIG. 2 is a schematic perspective view showing a state of a curved surface of a display module of a display apparatus in accordance with one exemplary embodiment.

As shown in FIGS. 1 and 2, a display apparatus 1 includes a display module 10 for displaying image information and a case 11 disposed on the outside of the display module 10 to protect the display module 10 and internal electric components of the display apparatus 1.

The display module 10 may include a display panel for displaying images and a frame attached to the display panel. In general, the display panel includes two pieces of glass, and is formed in such a manner that a liquid crystal layer is injected between a TFT substrate and a color substrate. Here, light emitting states of respective pixels are implemented differently from each other by driving circuits arranged in a matrix form, thereby forming an image on the display panel.

The case 11 is formed so as to surround a front surface edge and a rear surface of the display module 10, and includes a power supply for supplying power required for driving of the display module 10, a driving mode for converting external electrical signals into video and acoustic signals, and other components operating the display apparatus 1 therein.

A base 12 that is supported by an installation surface for installing the display apparatus 1 may be provided in the bottom of the case 11. The display module 10 and the base 12 may be connected by a stand 13 provided perpendicularly to the base 12.

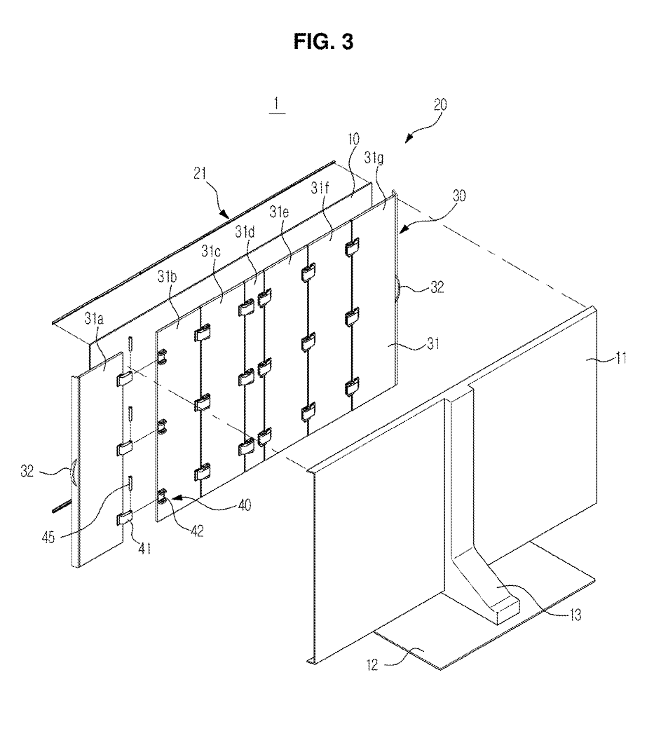

As shown in FIG. 3, the display apparatus 1 includes a deforming device 20 that is provided to transform the display module 10 into one of a flat state and a curved state.

The deforming device 20 is provided between the display module 10 and the case 11.

The deforming device 20 allows both ends of the display module 10 to be positioned forward than a center of the display module 10 so as to be prominent forward beyond the center of the display module 10.

In the present exemplary embodiment, each of the display module 10 and the case 11 are made of a material capable of being bent (i.e., deformed) to thereby be bent(deformed) by the deforming device 20.

Such a deforming device 20 may selectively allow the display module 10 to maintain a flat state, in which the display module 10 remains flat, or a curved state, in which both ends of the display module 10 are moved to be prominent forward beyond the center of the display module 10, by bending the display module 10.

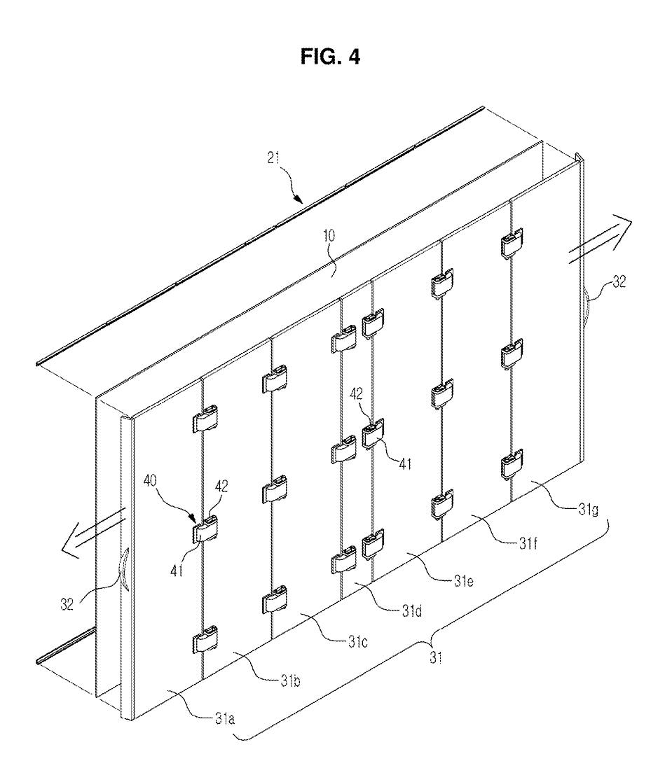

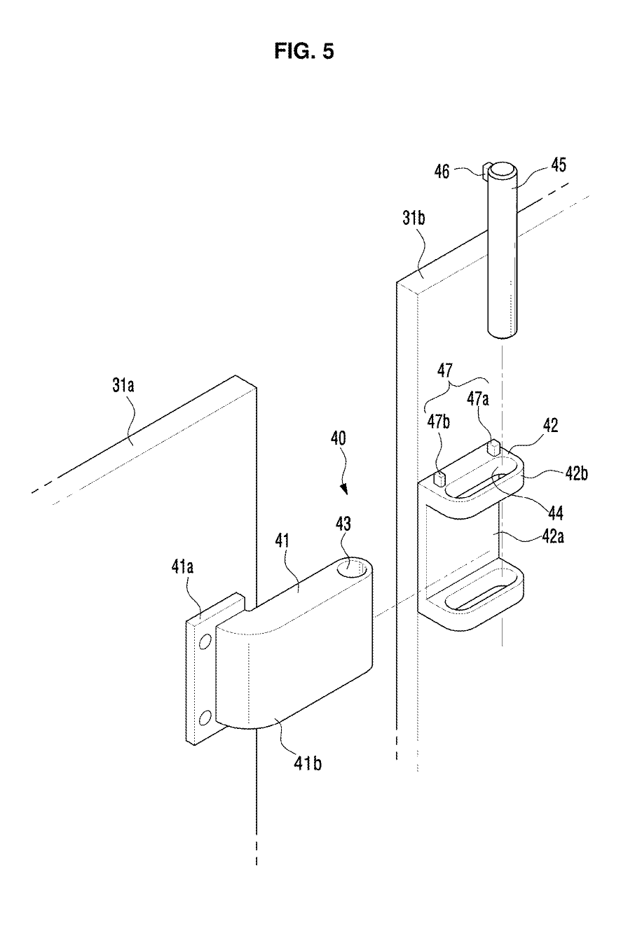

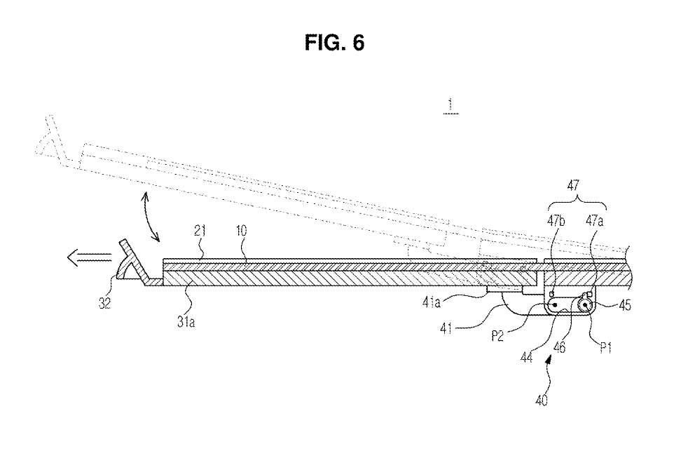

FIG. 3 is an exploded perspective view showing a deforming device of a display apparatus in accordance with one exemplary embodiment, FIG. 4 is a schematic perspective view showing a deforming device of a display module in accordance with one exemplary embodiment, FIG. 5 is a schematic view showing a hinge device of a deforming device in accordance with one exemplary embodiment, and FIG. 6 is a schematic view showing a state of a display module by a deforming device in accordance with one exemplary embodiment.

As shown in FIGS. 3 to 6, the deforming device 20 may include a frame 30 that is provided at a rear side of the display module 10, and a hinge unit 40 that is provided so as to connect in between the frame 30.

The frame 30 is configured to move both ends of the display module 10 in all directions.

The frame 30 includes a plurality of plates 31 provided so as to vertically support a rear surface of the display module 10.

The plates 31, in accordance with the present exemplary embodiment, may include first to seventh plates 31a, 31b, 31c, 31d, 31e, 31f, and 31g. In accordance with the present exemplary embodiment, seven plates 31a, 31b, 31c, 31d, 31e, 31f, and 31g are provided, but the exemplary embodiments are not limited thereto. For example, various numbers of the plates 31 may be provided.

Meanwhile, at both ends of the plurality of plates 31, a handle 32 is provided so as to enable a user to select one of the flat state and the curved state.

According to one exemplary embodiment, the handle 32 is exposed to the outside at both ends of the plates 31 between the case 11 and the display module 10 so that the handle 32 can be pulled by a user. In the present embodiment, an example in which the handle 32 is formed at one side of the first plate 31 and one side of the seventh plate 31 to be exposed to the outside of the case 11 is shown, but the exemplary embodiments are not limited thereto. For example, the handle 32 may be formed inside the case 11 to prevent the handle 32 from being exposed to the outside.

In addition, each of the plates 31 includes a fixing member 21 that is fixed to a rear surface of the display module 10.

The fixing member 21 may be formed into approximately a “□” shape, and may include a front surface portion that is brought into contact with front surfaces of upper and lower ends of the display module 10 and a support portion that is brought into contact with upper and lower surfaces of the plate 31 to be supported.

Hinge units 40 are provided so as to connect the respective plates 31 to vary curvature deformation of the frame 30 by a rotational torque thereof.

The hinge units 40 may be installed between the first and second plates 31a and 31b, between the second and third plates 31b and 31c, between the third and fourth plates 31c and 31d, between the fourth and fifth plates 31d and 31e, between the fifth and sixth plates 31e and 31f, and between the sixth and seventh plates 31f and 31g.

The hinge units 40 may include a first bracket 41 provided at one side plate 31, a second bracket 42 provided at an adjacent plate 31 so as to correspond to the first bracket 41, and a hinge shaft 45 provided so as to connect the first bracket 41 and the second bracket 42.

For example, the first bracket 41 is fixed by a fixing portion 41a at one side end of the first plate 31a, and includes a hinge hole 43 formed at an end of a body 41b extending from the fixing portion 41a.

The second bracket 42 is installed at one side end of the second plate 31b that is adjacent to the first plate 31a.

In this instance, it is preferable that the first bracket 41 be positioned in right ends of the first to fourth plates 31a, 31b, 31c, and 31d with respect to the fourth plate 31d, and the second bracket 42 be positioned in left ends thereof. In addition, it is preferable that the second bracket 42 be positioned in right ends of the fourth to seventh plates 31d, 31e, 31f, and 31f and the first bracket 41 be positioned in left ends thereof.

For example, the first bracket 41 of the hinge unit 40 is positioned in right end of the second plate 31b, and the second bracket 42 of the hinge unit 40 is positioned in the left end of the second plate 31b.

In this case, the first bracket 41 positioned in the right end of the second plate 31b is coupled to the second bracket 42 positioned in the left end of the third plate 31c.

The second bracket 42 positioned in the left end of the second plate 31b is coupled to the first bracket 41 positioned in the right end of the first plate 31a.

In contrary, the second bracket 42 of the hinge unit 40 is positioned in the right end of the sixth plate 31f, and the first bracket 41 of the hinge unit 40 is positioned in the left end of the sixth plate 31f.

The second bracket 42 positioned in the right end of the sixth plate 31f is coupled to the first bracket 41 positioned in the left end of the seventh plate 31g, and the first bracket 41 positioned in the left end of the sixth plate 31f is coupled to the second bracket 42 positioned in the right end of the fifth plate 31e.

Thus, when a user pulls the handle 32 in both directions, the first to third plates 31a, 31b, and 31c are rotated in the left direction with respect to the fourth plate 31d, and the fifth to seventh plates 31e, 31f, and 31g are rotated in the right direction with respect to the fourth plate 31d.

The second bracket 42 is fixed to the second plate 31 by a fixing portion 42a, and support portions 42b, having a sleeve 44 formed in the lengthwise direction, are provided at upper and lower ends of the second bracket 42. Here, the body 41b of the first bracket 41 passes between the upper and lower support portions 42b to be assembled.

Thus, the hinge shaft 45 is inserted into the sleeve 44 of the second bracket 42 and passes through the hinge hole 43 of the first bracket 41 to thereby be moved along the sleeve 44.

A stopper 46 is formed so as to protrude from an upper end of the hinge shaft 45. The stopper 46 of the hinge shaft 45 is supported by a support portion 47 formed on an upper surface of the second bracket 42.

The support portion 47 includes a first support portion 47a and a second support portion 47b formed in a position spaced apart from the first support portion 47a.

When the hinge shaft 45 is positioned in a first position P1 within the sleeve 44, the first support portion 47a causes the first plate 31a and the second plate 31b to contact with each other, such that the display module 10 maintains a flat state.

When the hinge shaft 45 is positioned in a second position P2 within the sleeve 44, the second support portion 47b causes the first plate 31a and the second plate 31b to be spaced apart from each other, such that the display module 10 maintains a curved state.

That is, the hinge unit 40 enters a non-operating state when the hinge shaft 45 is positioned at the first position P1, and enters an operating state when the hinge shaft 45 is positioned at the second position P2. According to an exemplary embodiment, the hinge unit 40 may enter the operating state by lateral movement of the handle 32.

According to an exemplary embodiment, the second support portion 47b includes an inclined portion 48 with a predetermined inclination (8) formed at one side thereof, so that the stopper 46 of the hinge shaft 45 can be rotated by the inclined portion 48.

When the hinge shaft 45 is rotated by the inclination (8) of the inclined portion 48, the first bracket 41 is rotated by the inclination (8) relative to the second plate 31 to be rotated forward.

The hinge units 40 connect the respective plates 31 so that the respective plates 31 are rotatable. According to the present exemplary embodiment, the hinge units 40 are arranged in the upper and lower portions of the plates 31 and the center thereof, but the exemplary embodiments are not limited thereto.

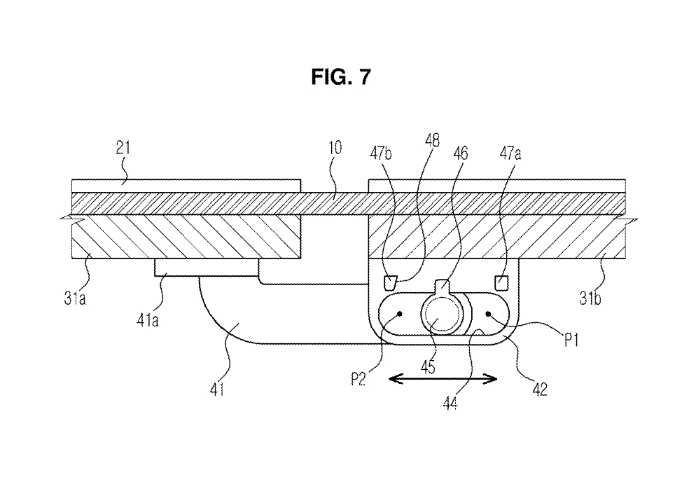

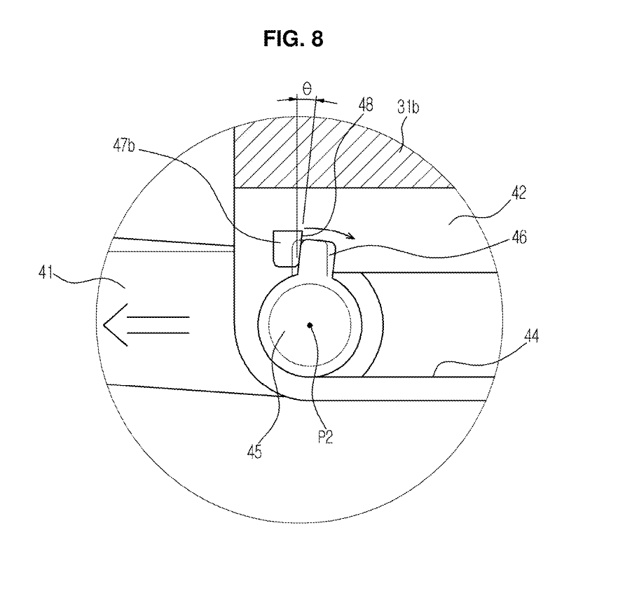

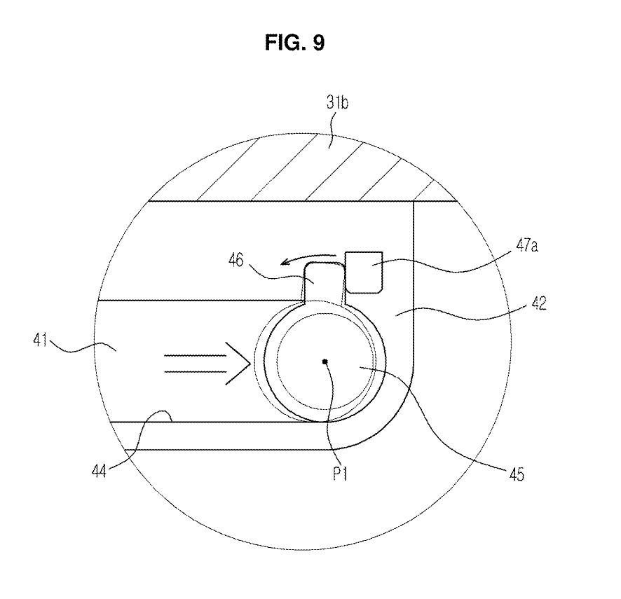

FIG. 6 is a schematic view showing a state of a display module by a deforming device in accordance with one exemplary embodiment, and FIGS. 7 to 9 are schematic views showing an operating state of a hinge unit in accordance with one exemplary embodiment.

With reference to FIGS. 6 to 9, operations of the deforming device 20 for selectively transforming the display module 10 of the display apparatus 1 into one of a flat state and a curved state will be described.

The display module 10 is usually used in a flat state.

In this instance, the first to seventh plates 31a, 31b, 31c, 31d, 31e, 31f, and 31g, respectively, provided on the rear surface of the display module 10 are brought into contact with each other, whereby a flat state of the display module 10 may be maintained.

Specifically, the hinge units 40 provided on the rear surface of the respective plates 31 are not operated and each hinge shaft 45 is positioned at the first position (P1) within the sleeve 44 and supported by the first support portion 47a.

When a user pulls the handle 32 in the left and right directions so that the display module 10 is transformed into a curved state, the hinge shaft 45 of the first bracket 41 of the hinge units 40 is moved from the first position P1 to the second position P2 within the sleeve 44 of the second bracket 42.

According to one exemplary embodiment, the first brackets 41 of the hinge units 40 connected to the first to third plates 31a, 31b, and 31c are rotated in the left direction to be moved, and the first brackets 41 of the hinge units 40 connected to the fifth to seventh plates 31e, 31f, and 31g are rotated in the right direction to be moved.

In this manner, the first to seventh plates 31a, 31b, 31c, 31d, 31e, 31f, and 31g are each rotated in the left and right directions to be moved, so that both ends of the display module 10 are moved forward, whereby a curved state of the display module 10 may be achieved.

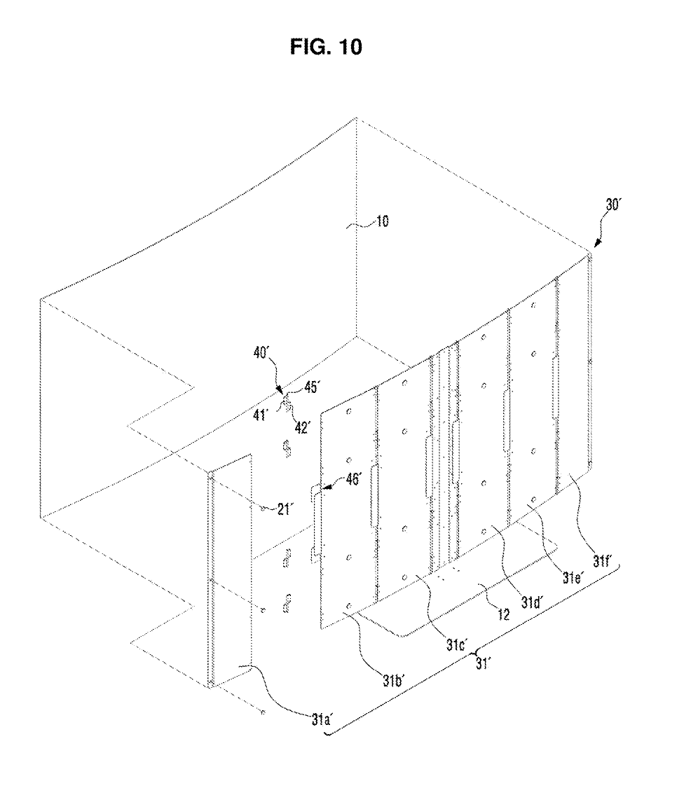

FIG. 10 is a schematic view showing a hinge unit 40 of a deforming device in accordance with another exemplary embodiment.

Hinge units 40′ may be provided in a plurality of plates 31′ provided to support the rear surface of the display module 10 in a vertical direction.

The plates 31′ in accordance with the present embodiment may include first to seventh plates 31a′, 31b′, 31c′, 31d′, 31e′, 31f′, and 31g′. In the present exemplary embodiment, an example in which seven plates 31′ including first to seventh plates 31a′, 31b′, 31c′, 31d′, 31e′, 31f′, and 31g′ are provided is shown, but the exemplary embodiments are not limited thereto. For example, various numbers of the plates 31′ may be provided.

Meanwhile, the plates 31a′ and 31f′ positioned at both ends of the display module 10 may include a fixing member 21′ provided to be fixed to the rear surface of the display module 10.

The hinge units 40′ provided to connect the respective plates 31′ may variably change a curvature of the frame 30′ and the display module 10 connected to the frame 30′ by a rotational torque of the hinge unit 40′.

The hinge units 40′ may be installed between first and second plates 31a′ and 31b′, between second and third plates 31b′ and 31c′, between third and fourth plates 31c′ and 31d′, between fourth and fifth plates 31d′ and 31e′, between fifth and sixth plates 31e′ and 31f′, and between sixth and seventh plates 31f′ and 31g′.

The hinge unit 40′ may include a first bracket 41′ provided at one side plate 31′ and a second bracket 42′ that is rotatably connected to a lower portion of the first bracket 41′ by the hinge shaft 45′.

For example, the first bracket 41′ is fixed at one side end of the first plate 31a′, and the second bracket 42′ connected by the hinge shaft 45 is fixed at one side end of the second bracket 31b′.

Meanwhile, a stopper 46′ formed to have a predetermined inclination is provided between the first bracket 41′ and the second bracket 42′.

Thus, the first bracket 41′ and the second bracket 42′ are rotated by the hinge unit 40′ and stopped at a certain position by the stopper 46′.

The hinge units 40′ connect the respective plates 31′ so that the respective plates 31′ are rotatable, and in the present embodiment, the hinge units 40′ are arranged in upper and lower portions of the plates 31′ and the center thereof, but the present invention is not limited thereto.

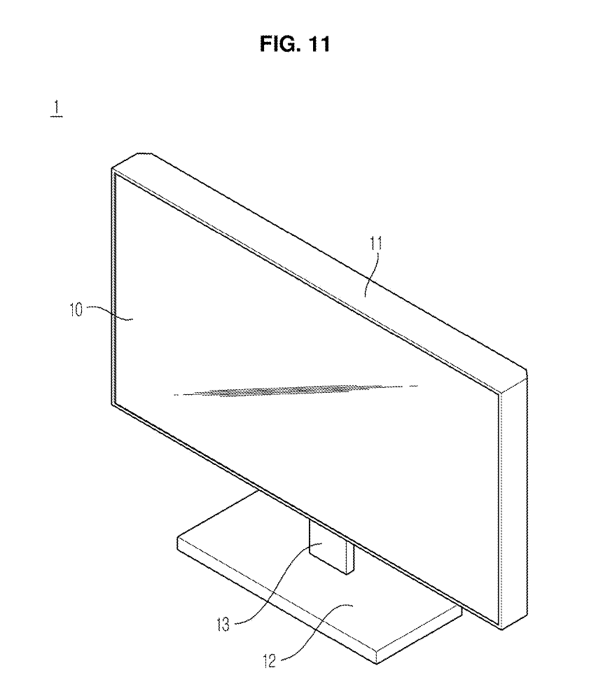

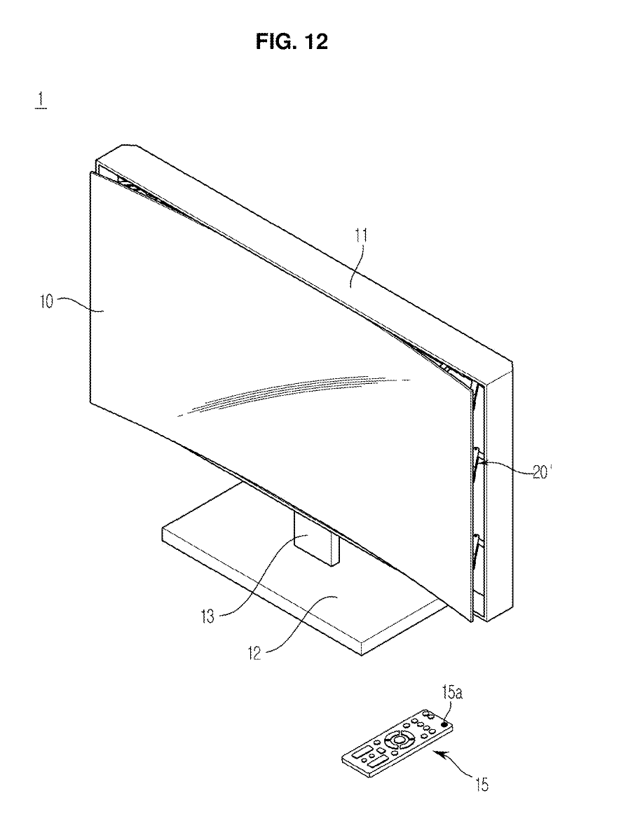

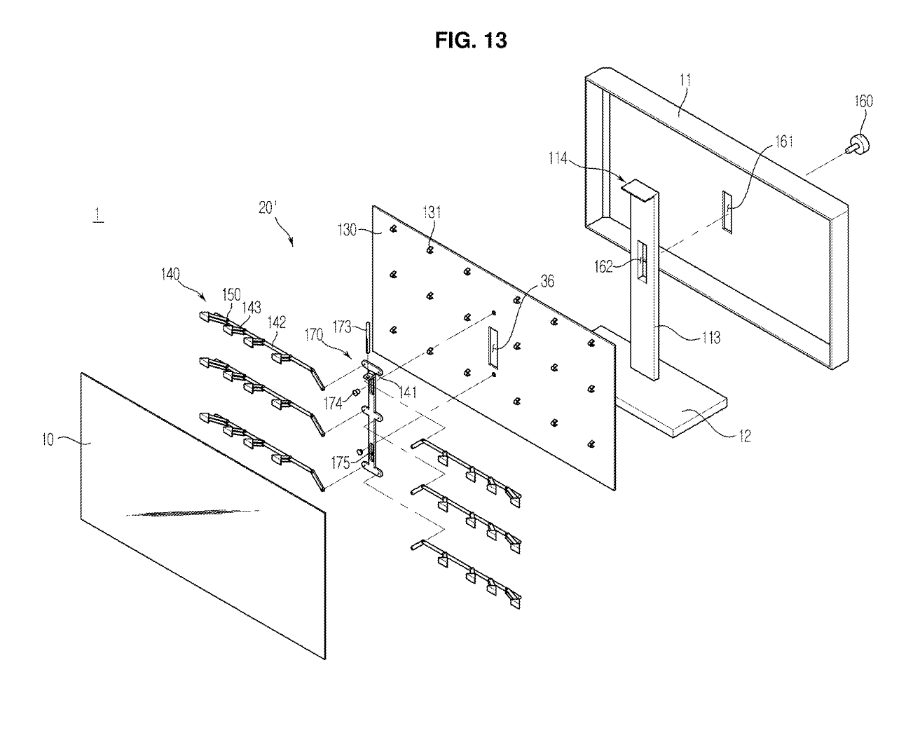

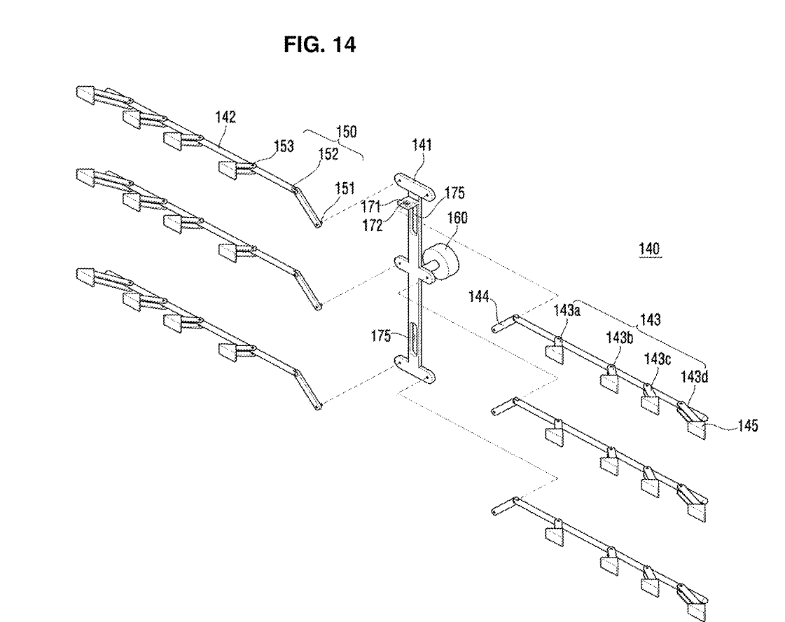

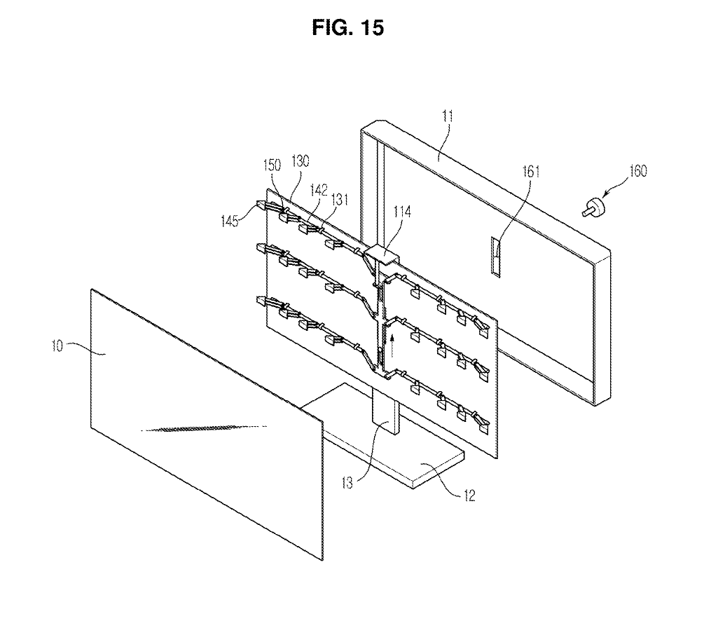

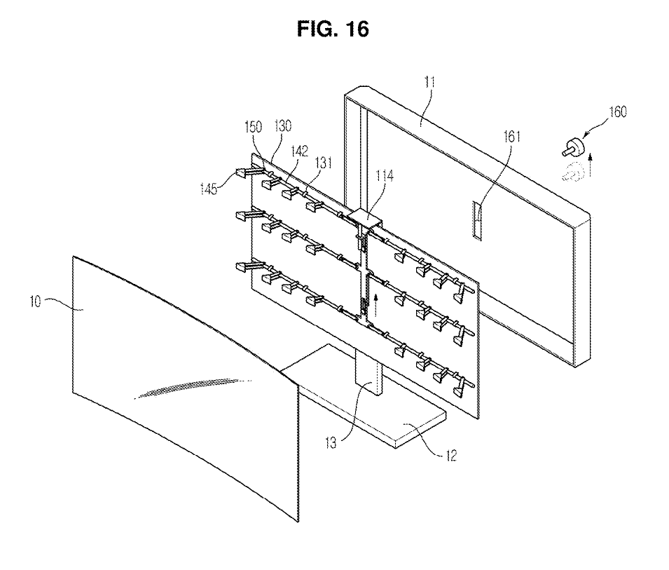

FIG. 11 is a schematic perspective view showing a display apparatus in accordance with another exemplary embodiment, FIG. 12 is a schematic perspective view showing a curved surface state of a display module of a display apparatus in accordance with another exemplary embodiment, FIG. 13 is a schematic exploded perspective view showing a deforming device of a display apparatus in accordance with another exemplary embodiment, FIG. 14 is a schematic exploded perspective view showing a deforming device in accordance with another exemplary embodiment, and FIGS. 15 and 16 are schematic views showing operations of a link member in accordance with another exemplary embodiment.

As shown in FIGS. 11 to 16, a deforming device 20′ is provided between the display module 10 and the case 11, and enables both ends of the display module 10 to be positioned in the front of a center thereof so that both of the ends of the display module 10 protrude forward from the center, thereby forming a curved state of the display module 10.

According to the present exemplary embodiment, each of the display module 10 and the case 11 are made of a material capable of being bent(deformed), such that the display module 10 and the case 11 may be bent(deformed) by the deforming device 20′.

Such a deforming device 20′ selectively transforms the display module 10 between a flat state and a curved state whose both ends protrude forward than the center by deforming the display module 10.

Meanwhile, the transformation of the display module 10 into a flat state and a curved state may be performed by operating the deforming device 20′ using a remote controller 15 provided in the display apparatus 1.

In this instance, a hot key 15a for selecting one of a flat state and a curved state may be provided in the remote controller 15. According to the present exemplary embodiment, the hot key 15a is provided in the remote controller 15 in order to implement a flat state or a curved state, but the exemplary embodiments are not limited thereto. For example, the flat state or the curved state may be selectively used using a menu key or the like of the remote controller 15.

The deforming device 20′ is provided between the display module 10 and the case 11, and enables both ends of the display module 10 to be positioned forward than a center of the display module 10 so as to be prominent forward beyond the center of the display module 10, thereby forming a curved state of the display module 10.

According to the present exemplary embodiment, each of the display module 10 and the case 11 is made of a material capable of being bent(deformed) to thereby be bent(deformed) by the deforming device 20′.

Such a deforming device 20′ selectively transforms the display module 10 into a flat state, in which the display module 10 maintains a flat state, and a curved state, in which both ends of the display module 10 are prominent forward beyond the center of the display module 10.

The deforming device 20′ may include a bracket 130 provided at a rear side of the display module 10 so that both ends of the display module 10 are moved forward. In addition, link members 140 are provided at a front side of the bracket 130 so as to support a rear surface of the display module 10, and a hinge 150 is provided to connect the link members 140.

The bracket 130 is fixed to a stand 13 so as to support the rear surface of the display module 10. A fixing support 114 is provided at an upper end of the stand 13 so as to fix the bracket 130 and the link member 140. According to the present exemplary embodiment, an example in which the bracket 130 is supported by the fixing support 114 of the stand 13 is shown, but the exemplary embodiments are not limited thereto.

For example, the bracket 130 may be fixed to the case 11.

A plurality of link members 140 are provided at the front side of the bracket 130 so as to support the rear surface of the display module 10.

The link member 140 may include a main link 141 that is disposed at a rear center of the display module 10, a first link 142 that is movably connected in both directions of the main link 141, a plurality of second links 143 which are rotatably connected in forward and rearward directions of the first link 142, and a connection link 144 that connects the main link 141 and the first link 142.

The main link 141 may be disposed at a center of the bracket 130, and a handle 160 is provided at a rear side of the main link 141 so that the handle 160 is vertically movable according to a user's intention.

The handle 160 may be coupled to a rear surface of the main link 141 and may protrude to the outside of the case 11 so as to enable a user to vertically move the handle 160.

In this instance, handle installation portions 161, 162, and 163 may be formed respectively in a center portion of the bracket 130, a center portion of the stand 13, and a center portion of the case 11 so that the handle 160 passes through the handle installation portions 161, 162, and 163.

The first link 142 is rotatably connected in each of upper and lower centers and a center portion of the main link 141 by the first hinge 151. According to the present exemplary embodiment, the first link 142 is connected to each of the upper and lower ends and the center portion of the main link 141 to support upper and lower ends and a center portion of the display module 10, but the exemplary embodiments are not limited thereto. For example, three or more first links may be provided.

A guide portion 170 for guiding vertical movement of the main link 141 may be provided in the main link 141. The guide portion 170 may include a guide protrusion 173 that protrudes downward from a bottom surface of a fixing support 114, and a guide panel 171 on which a guide hole 172 through which the guide protrusion 173 passes is formed.

The guide panel 171 protrudes forward from the main link 141, and guides vertical movement of the main link 141 in such a manner that the guide protrusion 173 formed downward from the fixing support 114 is inserted into the guide hole 172.

In addition, the main link 141 may include guide slots 175 that penetrate the main link 141 in a vertical direction and are formed at upper and lower portions of the front surface of the main link 141, and separate fixing members 174 are provided so as to be fitted into the guide slots 175.

The first link 142 may be movably installed in left and right directions of the bracket 130, and a support 131 for movably supporting the first link 142 is provided on the bracket 130.

The first link 142 is connected with the connection link 144 by a second hinge 152, and the connection link 144 is connected with the main link 141 by a first hinge 151, and therefore the first link 142 can be movable in left and right directions in conjunction with vertical movement of the main link 141.

The plurality of second links 143 may be provided, and arranged so as to be spaced apart from each other from the center of the first link 142 toward the outside.

A length of the second link 143 is variable, and it is preferable that the length of the second link 143 increase from a center of the second link 143 toward both ends thereof.

The four second links 143 may be arranged at right and left sides, the second link 143 having the shortest length may be disposed at a center portion, and the second link 143 having the longest length may be disposed at an outer end. In the present embodiment, the four second links 143 are disposed so as to be spaced apart from each other at a constant interval, but the present invention is not limited thereto. For example, four or more second links 143 may be provided.

The second link 143 may be rotatably connected with the first link 142 by a third hinge 153.

Thus, when the first link 142 is moved, the second link 143, which is connected to the first link 142, is rotated by the third hinge 153 such that the second link 143 is rotated forward.

When the second link 143 is moved forward, the display module 10 whose rear surface is supported by the second link 143 is moved forward, both ends of the display module 10 protrude forward from the center of the display module 10 by a length equal to the length of the second links 143, whereby a curved state of the display module 10 may be achieved.

A support 145 may be installed at an end of the second link 143. The support 145 may be provided so as to be brought into contact with the rear surface of the display module 10 so that the second link 143 can provide a more stable support for the display module 10.

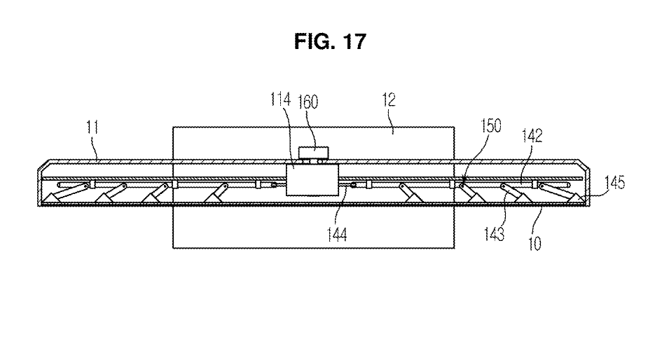

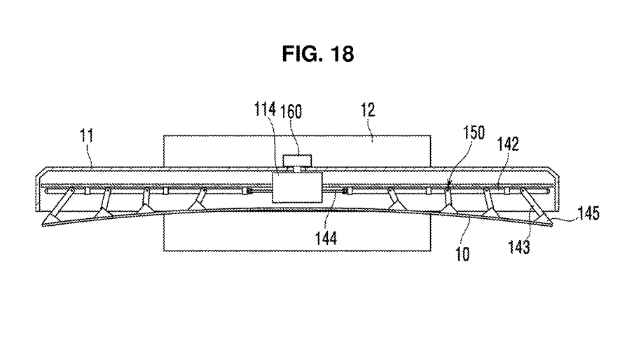

With reference to FIGS. 17 and 18, operations of the deforming device 20′ for selectively transforming the display module 10 of the display apparatus 1 into a flat state or a curved state will be described, according to an exemplary embodiment.

The display module 10 is usually used in a flat state.

According to one exemplary embodiment, the handle 160 provided on the rear surface of the case 11 of the display apparatus 1 is disposed in a lower position.

When a user moves the handle 160 upward so as to transform the display module 10 into a curved state, the main link 141 of the link member 140, which is connected to the handle 160, is moved upward.

When the main link 141 is moved upward, the connection link 144 connected to the main link 141 is moved upward, and each of the first links 142 connected to the connection link 144 are moved in left and right directions.

When the first link 142 is moved, the second link 143 connected with the first link 142 by the third hinge 153 is rotated forward by a rotation of the third hinge 153.

The second link 143 having a relatively long length is disposed at both of the ends thereof of the second link 142, and therefore both of the ends of the display module supported by the second link 143 protrude forward, thereby obtaining a curved state of the display module.

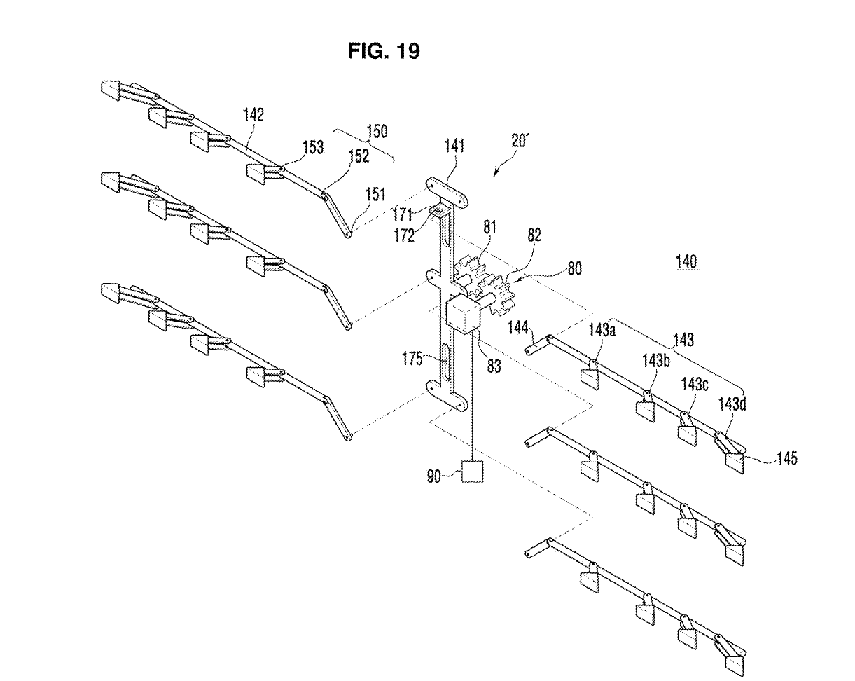

FIG. 19 is a schematic view showing a deforming device 20′ in accordance with another exemplary embodiment.

A deforming device 20′ may include a driving unit 80 provided so as to vertically move the main link 141.

The driving unit 80 may include a first gear 81 provided on the main link 141, a second gear 82 formed so as to be engaged with the first gear 81, and a motor 83 provided so as to rotate the second gear 82.

Meanwhile, the driving unit 80 may further include a controller 90 for operating the motor 83. The controller 90 may enable the main link 141 connected to the first gear 81 to be moved upward by controlling the rotation speed of the motor 83. In addition, when the main link 141 is moved upward, the connection link 144 connected to the main link 141 is moved upward, and each of the first links 142 connected to the connection link 144 is moved in left and right directions.

When the first link 142 is moved, the second link 143, which is connected to the first link 142 by the third hinge 153, is rotated forward by the third hinge 153.

The second links 143 disposed at both ends of the first link 142 are longer relative to the second links 143 disposed at the center of the first link 142, and therefore both of the ends of the display module 10 supported by the relative longer second links 143 protrude forward, thereby obtaining a curved state of the display module.

As is apparent from the above description, in accordance with the exemplary embodiments, the display module of the display apparatus may be selectively transformed into a flat state or a curved state.

In addition, curvature may vary depending on a user's preference, thereby freely implementing curvature deformation of the display module.

Although an exemplary embodiments have been shown and described, it would be appreciated by those skilled in the art that changes may be made in these exemplary embodiments without departing from the principles and spirit of the invention, the scope of which is defined in the claims and their equivalents.

What is claimed is:

1. A display apparatus comprising:
a display module configured to display an image and is capable of being deformed; and
a deforming device configured to transform the display module into a flat state or a curved state,
wherein the deforming device includes a frame provided at a rear side of the display module and a hinge unit configured to connect to the frame and enables the curvature of the frame to vary in response to a torque applied to the deforming device.

2. The display apparatus according to claim 1, wherein the frame includes:
a plurality of plates configured to vertically support the display module at the rear side of the display module; and
a handle provided at a first end plate and a second end plate.

3. The display apparatus according to claim 2, wherein the hinge unit includes:
a first bracket connected to one of the plurality of plates and having a hinge hole formed therein;
a second bracket connected to an adjacent one of the plurality of plates, configured to be connected to the first bracket and having a sleeve formed therein to correspond to the hinge hole; and
a hinge shaft configured to pass through the hinge hole and the sleeve to connect the one of the plurality of plates and the adjacent one of the plurality of plates.

4. The display apparatus according to claim 3, wherein the sleeve is formed in a horizontal direction to enable the first bracket to slide.

5. The display apparatus according to claim 3, wherein the hinge shaft further includes:
a stopper; and
a support portion corresponding to the stopper formed on the second bracket.

6. The display apparatus according to claim 5, wherein the support portion includes:
a first support position where the hinge shaft is positioned so that the plurality of plates contact each other; and
a second support portion in which the hinge shaft is positioned so that the plates are spaced apart from each other.

7. The display apparatus according to claim 1, wherein the frame is fixed to the display module by a fixing member.

8. The display apparatus according to claim 1, wherein the deforming device includes:
a bracket provided at the rear side of the display module;
a plurality of link members provided at a front side of the bracket configured to support a rear surface of the display module; and
the hinge unit configured to connect the plurality of link members.

9. The display apparatus according to claim 8, wherein the plurality of link members include:
a main link configured to move the display module in a vertical direction;
at least one first link moveably connected to a first side and a second side of the main link; and
a plurality of second links rotatably connected to the at least one first link and configured to rotate in a forward and a rearward direction.

10. The display apparatus according to claim 9, wherein the plurality of link members further include:
at least one connection link configured to connect the main link and the at least one first link.

11. The display apparatus according to claim 9, wherein the plurality of second links are spaced apart from each other in a direction from a center of the at least one first link toward an end of the first link opposite from the main link, and a length of the plurality of second links increases from the center of the at least one first link toward the end of the first link.

12. The display apparatus according to claim 10, wherein the hinge unit includes:
a first hinge configured to connect the main link and the at least one first link;
a second hinge configured to connect the at least one connection link and the at least one first link; and
a third hinge configured to connect the at least one first link and each of the plurality of second links.

13. The display apparatus according to claim 9, further comprising:
a handle configured to vertically move the main link.

14. The display apparatus according to claim 9, wherein the bracket further includes a guide configured to guide a movement of the main link.

15. The display apparatus according to claim 9, further comprising:
a driving unit configured to vertically move the main link.

16. The display apparatus according to claim 15, wherein the driving unit includes:
a first gear provided on the main link,
a second gear configured to be engaged with the first gear, and
a motor configured to rotate the second gear.

17. The display apparatus according to claim 16, wherein the driving unit includes a controller configured to operate the motor, and the controller is provided in the frame.

18. The display apparatus according to claim 17, further comprising:
a remote controller configured to connect to the controller.
